(19) United States
(12) Patent Application Publication
(10) Pub. No.: US 2026/0305072 A1
(43) Pub. Date: Oct. 1, 2026

(54) LIGHT EMITTING DISPLAY DEVICE

(71) Applicant: LG Display Co., Ltd., Seoul (KR)

(72) Inventor: Jeong-Chan YUN, Paju-si (KR)

(73) Assignee: LG Display Co., Ltd., Seoul (KR)

(21) Appl. No.: 19/410,713

(22) Filed: Dec. 5, 2025

(30) Foreign Application Priority Data
Mar. 28, 2025 (KR) 10-2025-0040177

(51) Int. Cl. H10K 59/121; H10K 59/124; H10K 59/131

(52) U.S. Cl. CPC H10K 59/1213; H10K 59/1216; H10K 59/124; H10K 59/131

(57) ABSTRACT

A light emitting display device includes a substrate on which subpixels are arranged, a data line disposed on the substrate and extending along a column direction on a side of each subpixel, and a driving transistor and a light emitting diode in each subpixel. The light emitting diode is connected to a source electrode of the driving transistor. A gate electrode of the driving transistor extends along the column direction, and the source electrode of the driving transistor is disposed between the gate electrode of the driving transistor and the data line. This arrangement increases the separation between the gate electrode and the data line, thereby reducing parasitic capacitance and improving signal stability within the subpixel.

### CROSS REFERENCE TO RELATED APPLICATIONS

The present application claims the priority benefit of Korean Patent Application No. 10-2025-0040177, filed in Republic of Korea on Mar. 28, 2025, which is hereby incorporated by reference in its entirety for all purposes as if fully set forth herein.

### BACKGROUND

### Technical Field

The present disclosure relates to a light emitting display device.

### Description of the Related Art

Recently, flat panel display devices with excellent characteristics such as thinness, weight reduction, and low power consumption have been widely developed and applied to various fields.

Among the flat panel display devices, light emitting display devices equipped with light emitting elements such as light emitting diodes are display devices that emit light when charges are injected into a light emitting layer formed between an anode and a cathode, and electrons and holes are paired and then extinguished.

### BRIEF SUMMARY

In conventional light emitting display devices, the gate electrode of the driving transistor is positioned close to the data line. This proximity creates a parasitic capacitance between the two structures, which can distort the gate voltage of the driving transistor and lead to vertical crosstalk. The present disclosure provides a light emitting display device configured to reduce vertical crosstalk by alleviating the parasitic capacitance that occurs between the gate electrode of the driving transistor and the data line.

In particular, the present disclosure presents a redesigned subpixel layout that reduces vertical crosstalk in light emitting display devices. In this structure, the gate electrode of the driving transistor is arranged to extend parallel to the data line rather than crossing it. This geometric adjustment increases the physical separation between these conductive components, which reduces the parasitic capacitance that can distort the gate voltage of the driving transistor.

A further aspect involves placing a circuit element such as the source electrode of the driving transistor or the storage capacitor between the gate electrode and the data line. This interposed structure functions as both a spatial and an electrical buffer that suppresses parasitic coupling. The storage capacitor is formed using overlapping semiconductor and metal regions, allowing it to perform its charge holding function while also contributing to electrical shielding.

Through these layout and stacking strategies, the structure secures increased separation and shielding within each subpixel. As a result, the arrangement reduces parasitic capacitance, mitigates gate voltage distortion, and suppresses vertical crosstalk, leading to improved image uniformity without increasing pixel area or altering the fundamental pixel driving circuit.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a light emitting display device includes a substrate on which subpixels are arranged, a data line disposed on the substrate, connected to the subpixel, and extending along a column direction on a side of the subpixel, and a driving transistor and a light emitting diode in the subpixel, the light emitting diode being connected to a source electrode of the driving transistor, wherein a gate electrode of the driving transistor extends along the column direction, and wherein the source electrode of the driving transistor is disposed between the gate electrode of the driving transistor and the data line.

In another aspect, a light emitting display device includes a substrate on which subpixels are arranged, a data line disposed on the substrate, connected to the subpixel, and extending along a side of the subpixel, and a driving transistor and a light emitting diode in the subpixel, the light emitting diode being connected to the driving transistor, wherein a gate electrode of the driving transistor extends along an extension direction of the data line, and wherein a circuit element of the subpixel is disposed between the gate electrode of the driving transistor and the data line.

It is to be understood that both the foregoing general description and the following detailed description are exemplary and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a view schematically illustrating a light emitting display device according to an embodiment of the present disclosure;

FIG. 2 is a view schematically illustrating a circuit structure of a subpixel of a light emitting display device according to an embodiment of the present disclosure;

FIG. 3 is a plan view schematically illustrating a subpixel of a light emitting display device according to an embodiment of the present disclosure;

FIG. 4 is a view enlarging a driving circuit region of FIG. 3;

FIG. 5 is a cross-sectional view taken along a line V-Vʹ of FIG. 3;

FIG. 6 is a cross-sectional view taken along a line VI-VIʹ of FIG. 3;

FIG. 7 is a plan view schematically illustrating an arrangement structure of a gate electrode of a driving transistor and a data line in a subpixel of a light emitting display device according to an embodiment of the present disclosure; and

FIG. 8 is a plan view schematically illustrating an arrangement structure of a gate electrode of a driving transistor and a data line in a subpixel of a light emitting display device according to a comparative example.

### DETAILED DESCRIPTION

Advantages and features of the present disclosure and methods of achieving them will be apparent with reference to the embodiments described below in detail with the accompanying drawings. However, the present disclosure is not limited to the embodiments disclosed below, but can be realized in a variety of different forms, and only these embodiments allow the present disclosure to be complete. The present disclosure is provided to fully inform the scope of the disclosure to the skilled in the art of the present disclosure, and the present disclosure may be defined by the scope of the claims.

The shapes, sizes, proportions, angles, numbers, and the like disclosed in the drawings for explaining the embodiments of the present disclosure are illustrative, and the present disclosure is not limited to the illustrated matters. The same reference numerals refer to the same components throughout the description.

Furthermore, in describing the present disclosure, if it is determined that a detailed description of the related known technology unnecessarily obscure the subject matter of the present disclosure, the detailed description thereof can be omitted. When “comprising,” “including,” ‘“having,” “consisting,” and the like are used in this disclosure, other parts can be added unless “only” is used. When a component is expressed in the singular, cases including the plural are included unless specific statement is described.

In interpreting the components, even if there is no separate explicit description, it is interpreted as including a margin range.

In the case of a description of a positional relationship, for example, when the positional relationship of two parts is described as “on,” “over,” “above,” “below,” “beside,” “under,” and the like, one or more other parts can be positioned between such two parts unless “right” or “directly” is used.

In the case of a description of a temporal relationship, for example, when a temporal precedence is described as “after,” “following,” “before,” and the like, cases that are not continuous can be included unless “directly” or “immediately” is used.

As used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" and "in contact" should be interpreted in the same manner.

In describing components of the present disclosure, terms such as first, second and the like can be used. These terms are only for distinguishing the components from other components, and an essence, order, sequence, or number of the components is not limited by the terms.

Respective features of various embodiments of the present disclosure can be partially or wholly connected to or combined with each other and can be technically interlocked and driven variously, and respective embodiments can be independently implemented from each other or can be implemented together with a related relationship.

Hereinafter, embodiments of the present disclosure are described in detail with reference to the drawings. Meanwhile, in the following embodiments, the same and like reference numerals are assigned to the same and like components, and detailed descriptions thereof may be omitted.

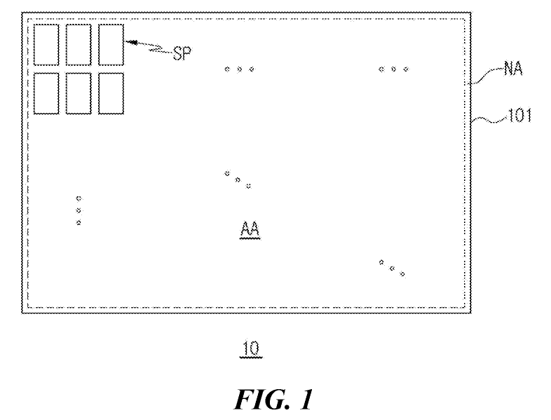

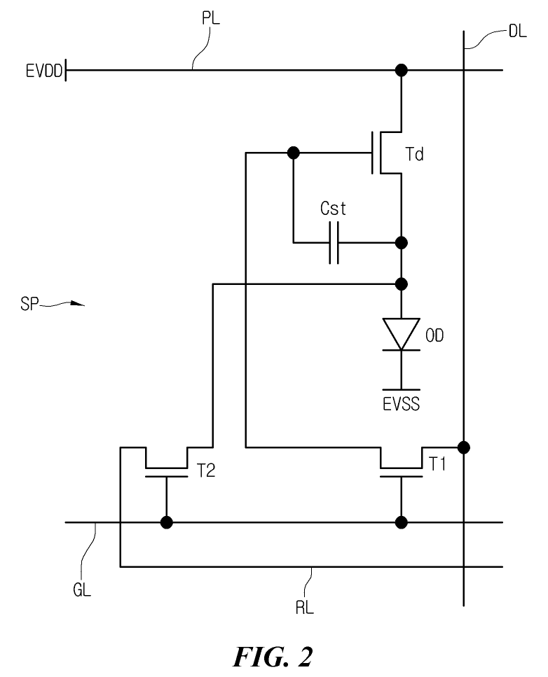

FIG. 1 is a view schematically illustrating a light emitting display device according to an embodiment of the present disclosure. FIG. 2 is a view schematically illustrating a circuit structure of a subpixel of a light emitting display device according to an embodiment of the present disclosure.

Prior to a detailed description, the light emitting display device 10 according to the embodiment of the present disclosure can include any type of display devices that include light emitting diodes OD, which are self-luminous elements, to display images.

In this embodiment, for convenience of explanations, an organic light emitting display device is used as an example of the light emitting display device 10. The light emitting display device 10 can be a top emission type or bottom emission type display device.

Referring to FIGS. 1 and 2, the light emitting display device 10 (or its light emitting display panel) of this embodiment can include a display region AA for displaying an image and a non-display region NA arranged around the display region AA.

In the display region AA, a plurality of subpixels SP arranged along a plurality of row lines (or horizontal lines) and a plurality of column lines (or vertical lines) can be formed on a substrate 101.

In addition, a plurality of gate lines GL extending along the row direction (or horizontal direction or first direction) and a plurality of data lines DL extending along the column direction (or vertical direction or second direction) on a side of the subpixel SP can be formed on the substrate 101.

In addition, a power line PL that transmits a high-potential driving voltage (or first driving voltage) EVDD to the subpixel SP can be formed on the substrate 101. A reference line (or sensing line) RL that transmits a sensing voltage for compensation of characteristics of a driving transistor Td, for example, threshold voltage and/or mobility compensation, and also provides a reference voltage to the subpixel SP can be formed on the substrate 101.

The plurality of subpixels SP arranged on the substrate 101 can include subpixels SP of different colors that constitute a pixel which is a unit for displaying a color image.

In this regard, the plurality of subpixels SP can include subpixels SP that respectively display first, second, and third colors, for example, red, green, and blue subpixels SP, but not limited thereto. As another example, the plurality of subpixels SP that constitute the pixel can further include a white subpixel SP that displays white.

The red, green, and blue subpixels SP can be arranged in various forms. For example, the red, green, and blue subpixels SP can be arranged in a stripe type in which subpixels SP of the same color are arranged in the column direction and subpixels SP of different colors are arranged alternately and repeatedly in the row direction, but not limited thereto.

Each subpixel SP can include the light emitting diode OD. In addition, the subpixel SP can include a pixel driving circuit that drives the light emitting diode OD.

The pixel driving circuit can include a plurality of transistors, including a driving transistor Td, and at least one capacitor. In this case, the driving transistor Td can be turned on during an emission period to generate an emission current, and the emission current can be provided to the light emitting diode OD to perform emission operation.

An example of a circuit structure of the subpixel (SP) can be described with reference to FIG. 2. In FIG. 2, for convenience of explanation, the pixel driving circuit for driving the subpixel SP is illustrated as having a 3T1C structure configured with three transistors T1, T2, and Td and one capacitor Cst. Meanwhile, the structure of FIG. 2 is an example, and the pixel driving circuit can be configured with a different structure.

Meanwhile, in the description below, terms, source electrode and drain electrode of a transistor are used to distinguish two electrodes connected to a semiconductor layer, and the terms can be used interchangeably in some cases.

The subpixel SP can include a first transistor T1 and a second transistor T2, which are switching transistors, a driving transistor Td, a storage capacitor Cst, and a light emitting diode OD. The first transistor T1 can be a transistor that controls data supply, and the second transistor T2 can be a transistor that senses driving characteristics.

The first transistor T1 can be connected to the corresponding gate line GL and data line DL. In this regard, a drain electrode (or source electrode) of the first transistor T1 can be connected to the data line DL, and a gate electrode of the first transistor T1 can be connected to the gate line GL. The first transistor T1 may be connected between the data line DL and the gate electrode of the driving transistor Td .

The driving transistor Td can have a gate electrode connected to a source electrode (or drain electrode) of the first transistor T1, a drain electrode (or source electrode) to which a high-potential driving voltage EVDD is applied, and a source electrode (or drain electrode) connected to an anode electrode (or first electrode) of the light emitting diode OD.

The second transistor T2 can be connected to the corresponding gate line GL and reference line RL. In this regard, a drain electrode (or source electrode) of the second transistor T2 can be connected to the reference line RL, a gate electrode of the second transistor T2 can be connected to the gate line GL, and a source electrode (or drain electrode) of the second transistor T2 can be connected to a node between the driving transistor Td and the light emitting diode OD. In other words, the source electrode of the second transistor T2 can be connected to the source electrode of the driving transistor Td and the anode electrode of the light emitting diode OD. The second transistor T2 may be connected between the reference line RL and the source electrode of the driving transistor Td.

As such, in this embodiment, an example is given in which the first transistor T1 and the second transistor T2 in the subpixel SP are connected to the same gate line GL and are driven by receiving the same gate signal. As another example, the second transistor T2 can be configured to be driven by being connected to a different gate line from the first transistor T1.

A cathode electrode (or second electrode) of the light emitting diode OD can be applied with a low-potential driving voltage (or second driving voltage) EVSS. The low-potential driving voltage EVSS can be a voltage of a lower potential than the high-potential driving voltage EVDD, and can include a ground voltage.

The storage capacitor Cst can be connected between the gate electrode and the source electrode of the driving transistor Td.

In the configuration described above, in operating in a display mode for displaying an image, when a gate signal is applied through the gate line GL, the first transistor T1 can be turned on, and a data signal (or data voltage) can be input to the subpixel SP, so that the data signal can be applied to the gate electrode of the driving transistor Td.

At this time, the second transistor T2 can be turned on, and a reference voltage can be applied to the source electrode of the driving transistor Td. Accordingly, the data signal and the reference voltage can be applied to both electrodes of the storage capacitor Cst, so that the data signal can be stored in the storage capacitor Cst.

Then, when the gate signal is not applied to the gate line GL and is turned off, the first and second transistors T1 and T2 can be turned off, the driving transistor Td can be turned on, and the emission current (or driving current) corresponding to the applied data signal can flow to the light emitting diode OD through the driving transistor Td. Accordingly, light corresponding to the emission current can be generated and output from the light emitting diode OD during the emission period.

Meanwhile, in operating in a compensation mode for compensating for the driving transistor Td, a sensing data signal can be applied to the subpixel SP and a sensing voltage can be provided to the reference line RL through the second transistor T2. Based on the sensing voltage, the data signal for image display can be compensated, and the compensated data signal can be applied to the subpixel SP to compensate for the driving transistor Td.

Meanwhile, in this embodiment, the gate electrode of the driving transistor Td can be formed to be positioned as far away as possible from the data line DL. As such, increasing a distance between the gate electrode of the driving transistor Td and the data line DL can reduce or prevent occurrence of a parasitic capacitance between the gate electrode of the driving transistor Td and the data line DL.

Thus, a phenomenon of the data signal applied to the data line DL interfering with the voltage of the gate electrode of the driving transistor Td can be reduced or prevented.

Therefore, distortion of the gate voltage of the driving transistor Td caused by the data signal of the data line DL can be reduced or prevented, thereby alleviating a vertical crosstalk caused by the parasitic capacitance.

As such, in this embodiment, to mitigate the parasitic capacitance, the distance between the gate electrode of the driving transistor Td and the data line DL can be increased by modifying a design of the pixel driving circuit.

In this regard, for example, the gate electrode of the driving transistor Td can be arranged substantially parallel to the column direction which is an extension direction of the data line DL, or may extend along the column direction, and a circuit element, such as an electrode pattern or the storage capacitor Cst, can be arranged between the gate electrode of the driving transistor Td and the data line DL.

Accordingly, the distance between the gate electrode of the driving transistor Td in the subpixel SP and the corresponding data line DL can be increased, so that the occurrence of the parasitic capacitance between the gate electrode of the driving transistor Td and the data line DL can be reduced.

Hereinafter, the structure of the subpixel SP that can reduce the parasitic capacitance between the gate electrode of the driving transistor Td and the data line DL by increasing the distance between the gate electrode of the driving transistor Td and the data line DL can be described in more detail.

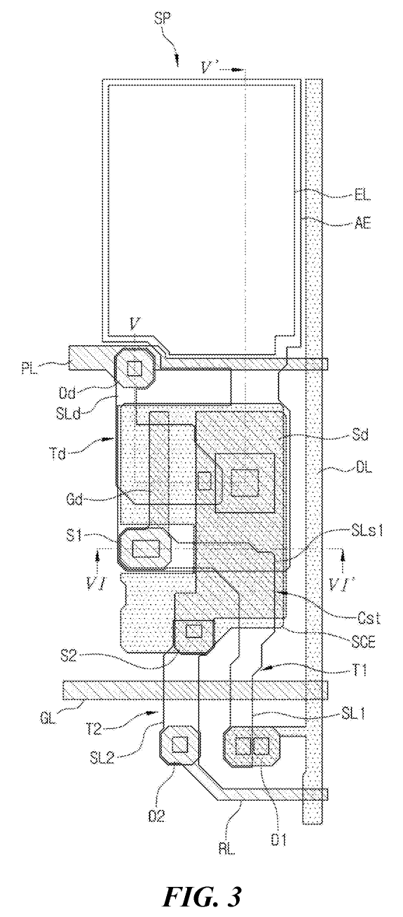

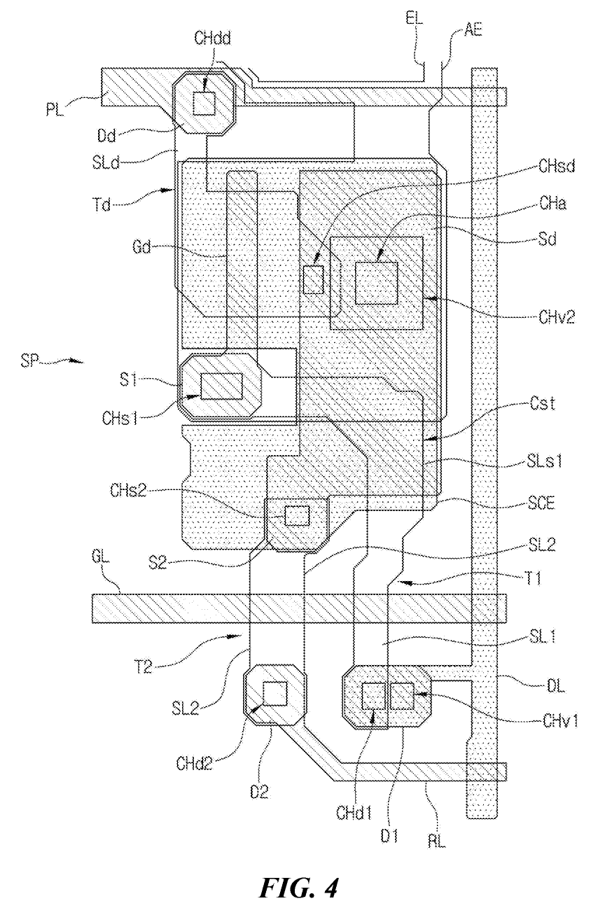

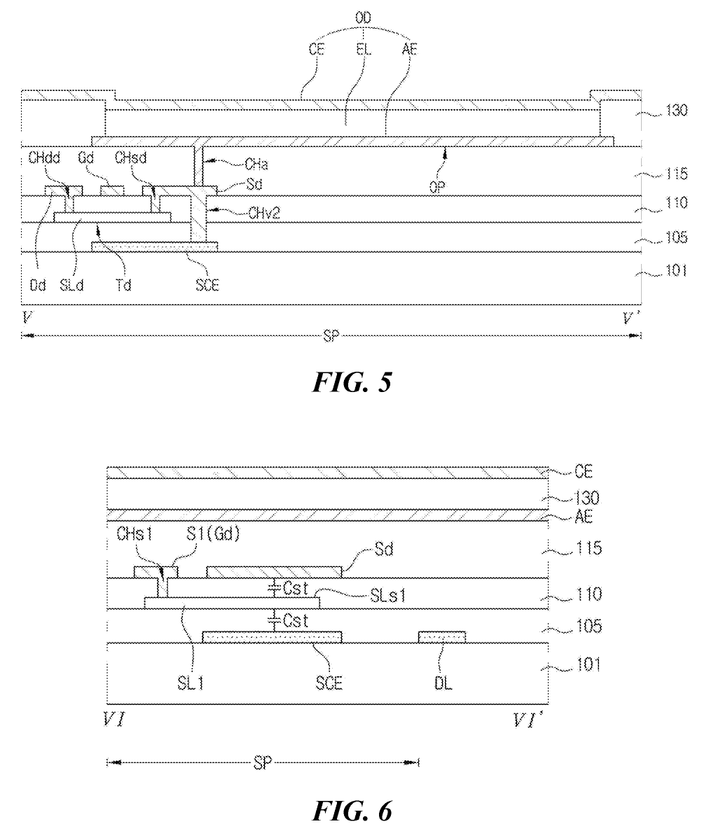

FIG. 3 is a plan view schematically illustrating a subpixel of a light emitting display device according to an embodiment of the present disclosure. FIG. 4 is a view enlarging a driving circuit region of FIG. 3. FIG. 5 is a cross-sectional view taken along a line V-Vʹ of FIGS. 3, and 6 is a cross-sectional view taken along a line VI-VIʹ of FIG. 3.

Referring to FIGS. 3 - 6, along with FIGS. 1 and 2, the subpixels SP can be arranged on the substrate 101 of the light emitting display device 10 of this embodiment, and in each subpixel SP, a driving circuit region in which a pixel driving circuit is disposed, and an emission region in which the light emitting diode OD is disposed can be defined.

In the driving circuit region, the first and second transistors T1 and T2, the driving transistor Td, and the storage capacitor Cst, which constitute the pixel driving circuit, can be formed on the substrate 101.

In addition, the emission region can be located on one side, for example, an upper side, of the driving circuit region, and the light emitting diode OD stacked on the pixel driving circuit can be formed in the emission region.

The data line DL, which provides a data signal to the subpixel SP, can extend in the column direction, and the gate line GL, which provides a gate signal to the subpixel SP, can extend in the row direction.

Meanwhile, in this embodiment, for convenience of explanation, a case where the data line DL is arranged on one side of the subpixel SP connected to the data line DL (or corresponding to the data line DL), for example, on the right side of the subpixel SP is taken as an example, but not limited thereto. Furthermore, a case where the gate line GL is arranged on one side of the subpixel SP connected to the gate line GL (or corresponding to the gate line GL), for example, on the lower side of the subpixel SP is taken as an example, but not limited thereto.

The power line PL, which transmits the high-potential driving voltage EVDD, can extend, for example, in the row direction, but not limited thereto. Furthermore, the reference line RL, which transmits the reference voltage and the sensing voltage, can extend, for example, in the row direction, but not limited thereto.

In the pixel driving circuit formed in the subpixel SP, the first transistor T1 can include the source electrode (or first source electrode) S1, the drain electrode (or first drain electrode) D1, the gate electrode (or first gate electrode), and the semiconductor layer (or first semiconductor layer) SL1.

The second transistor T2 can include the source electrode (or second source electrode) S2, the drain electrode (or second drain electrode) D2, the gate electrode (or second gate electrode), and the semiconductor layer (or second semiconductor layer) SL2.

The driving transistor Td can include the source electrode (or third source electrode) Sd, the drain electrode (or third drain electrode) Dd, the gate electrode (or third gate electrode) Gd, and the semiconductor layer (or third semiconductor layer) SLd.

The storage capacitor Cst can include two electrodes, e.g., a first capacitor electrode and a second capacitor electrode which are stacked in a direction perpendicular to a plane of the substrate 10 with an insulating layer interposed therebetween, and face each other (or overlap each other).

The light emitting diode OD formed in the subpixel SP can include the anode electrode AE, the emitting layer EL, and the cathode electrode CE which are sequentially stacked upward.

The stacked structure of the pixel driving circuit and the light emitting diode OD provided in the subpixel SP, and lines that transmit signals and voltages to the subpixel SP can be described as follows.

Referring to FIGS. 3-6, the substrate 101 can be, for example, a glass substrate or a plastic substrate having insulating property. As another example, the substrate 101 can use a silicon wafer. In this embodiment, for convenience of explanation, a case where the substrate 101 is formed of a glass substrate or a plastic substrate is taken as an example.

For example, the data line DL can be formed in a first metal layer on the substrate 101. In addition, in the first metal layer, for example, a capacitor electrode pattern SCE formed within the subpixel SP can be formed. The capacitor electrode pattern SCE can constitute one electrode of the storage capacitor Cst, for example, a second capacitor electrode.

On the first metal layer, for example, a buffer layer (or first insulating layer) 105 can be formed. The buffer layer 105 can be formed of, for example, an inorganic insulating material such as silicon oxide (SiO2) or silicon nitride (SiNx), but not limited thereto.

On the buffer layer 105, the semiconductor layers SL1, SL2, and SLd of the first and second transistors T1 and T2, and the driving transistor Td can be formed. The semiconductor layers SL1, SL2, and SLd can each include a central channel region, and source and drain regions on both side of the channel region. The source and drain regions of the semiconductor layers SL1, SL2, and SLd can be regions doped with impurities and can substantially have conductivity.

The semiconductor layers SL1, SL2, and SLd can be formed of, for example, polycrystalline silicon, amorphous silicon, or an oxide semiconductor, but not limited thereto.

A gate insulating layer (or second insulating layer) 110 can be formed on the semiconductor layers SL1, SL2, and SLd. The gate insulating layer 110 can be formed of, for example, an inorganic insulating material such as silicon oxide (SiO2) or silicon nitride (SiNx), but not limited thereto.

For example, the gate electrodes of the first and second transistors T1 and T2, and the driving transistor Td can be formed in a second metal layer on the gate insulating layer 110. Furthermore, the source electrodes S1, S2, and Sd and the drain electrodes D1, D2, and Dd of the first and second transistors T1 and T2, and the driving transistor Td can be formed in the second metal layer.

The source electrode S1 of the first transistor T1 can be formed integrally with the gate electrode Gd of the driving transistor Td. In other words, an electrode pattern that functions as the source electrode S1 of the first transistor T1 and the gate electrode Gd of the driving transistor Td can be provided in the subpixel SP. Accordingly, it can be said that a portion of the gate electrode Gd of the driving transistor Tdfunctions as the source electrode S1 of the first transistor T1.

In addition, the source electrode S2 of the second transistor T2 can be formed integrally with the source electrode Sd of the driving transistor Td. In other words, an electrode pattern that functions as the source electrode S2 of the second transistor T2 and the source electrode Sd of the driving transistor Td can be provided in the subpixel SP.

Furthermore, the gate line GL can be formed, for example, in the second metal layer. A portion of the gate line GL can be used as the gate electrode of the first transistor T1, and another portion of the gate line GL can be used as the gate electrode of the second transistor T2.

In addition, for example, the power line PL and the reference line RL can be formed in the second metal layer.

In the above case, the drain electrode D1 of the first transistor T1 can contact the drain region of the corresponding semiconductor layer SL1 through, for example, a contact hole CHd1 formed in the gate insulating layer 110. The source electrode S1 of the first transistor T1 can contact the source region of the corresponding semiconductor layer SL1 through, for example, a contact hole CHs1 formed in the gate insulating layer 110.

The drain electrode D2 of the second transistor T2 can contact the drain region of the corresponding semiconductor layer SL2 through, for example, a contact hole CHd2 formed in the gate insulating layer 110. The source electrode S2 of the second transistor T2 can contact the source region of the corresponding semiconductor layer SL2 through, for example, a contact hole CHs2 formed in the gate insulating layer 110.

The drain electrode Dd of the driving transistor Td can be in contact with the drain region of the corresponding semiconductor layer SLd through, for example, a contact hole CHdd formed in the gate insulating layer 110. The source electrode Sd of the driving transistor Td can be in contact with the source region of the corresponding semiconductor layer SLd through, for example, a contact hole CHsd formed in the gate insulating layer 110.

Meanwhile, the drain electrode D1 of the first transistor T1 can be in contact with the corresponding data line DL through, for example, a contact hole CHv1 formed in the gate insulating layer 110 and the buffer layer 105. The contact hole CHv1 formed in the gate insulating layer 110 and the buffer layer 105 and the contact hole CHd1 formed in the gate insulating layer 110 can be formed integrally, so that the drain electrode D1 of the first transistor T1 can be configured to be in contact with the corresponding semiconductor layer SL1 and the data line DL.

In addition, the source electrode Sd of the driving transistor Td can be in contact with and be connected to the capacitor electrode pattern SCE disposed below the source electrode Sd or disposed below the semiconductor layer of the first transistor T1, for example, through a contact hole CHv2 formed in the gate insulating layer 110 and the buffer layer 105.

In the case of the above configuration, for example, the capacitor electrode pattern SCE and/or the source electrode Sd of the driving transistor Td connected to the capacitor electrode pattern SCE can constitute the second capacitor electrode of the storage capacitor Cst. In addition, the source region SLs1 of the semiconductor layer SL1 of the first transistor T1 disposed to overlap the second capacitor electrode and connected to the gate electrode Gd of the driving transistor Td can constitute the first capacitor electrode of the storage capacitor Cst.

In this regard, when viewed in plan view, the source region SLs1 of the semiconductor layer SL1 of the first transistor T1 can be formed to extend, for example, across the capacitor electrode pattern SCE and/or the source electrode Sd of the driving transistor Td connected to the capacitor electrode pattern SCE. The source region SLs1 of the semiconductor layer SL1 of the first transistor T1 may overlap the source electrode Sd of the driving transistor Td on the source region SLs1 and overlap the capacitor electrode pattern SCE. Here, the source region SLs1 of the semiconductor layer SL1 of the first transistor T1 can be configured such that, for example, one end portion of the source region SLs1 contacting the source electrode S1 is located further away from the data line DL than the other end portion of the source region SLs1 contacting the channel region.

Accordingly, the source region SLs1 of the semiconductor layer SL1 of the first transistor T1 having conductivity, and the capacitor electrode pattern SCE overlapping the source region SLs1 and disposed below the source region SL1 and/or the source electrode Sd of the driving transistor Td overlapping the source region SLs1 and disposed on the source region SLs1 can implement the storage capacitor Cst.

On the transistors T1, T2, and Td, and the storage capacitor Cst configured as described above, at least one insulating layer can be formed. In this embodiment, a case where a passivation layer (or a planarization layer or a third insulating layer) 115 is formed on the transistors T1, T2, and Td or on the second metal layer is taken as an example.

The passivation layer 115 can be formed of, for example, an inorganic insulating material such as silicon oxide (SiO2) or silicon nitride (SiNx), and/or an organic insulating material such as photoacrylic or benzocyclobutene.

The anode electrode AE can be formed on the passivation layer 115 for each subpixel (SP). Here, in a case where the light emitting display device 10 is a bottom emission type display device, the anode electrode AE can include, for example, a transparent conductive layer formed of a transparent conductive material such as ITO or IZO. In a case where the light emitting display device 10 is a top emission type display device, the anode electrode AE can include, for example, a reflective layer formed of a highly reflective metal such as Ag.

The anode electrode AE can contact the source electrode Sd of the driving transistor Td, for example, through a contact hole CHa formed in the passivation layer 115.

On the passivation layer 115 and the anode electrode AE, a bank 130 can be formed along a boundary of each subpixel SP. The bank 130 can include an opening that exposes the anode electrode AE, and can cover an edge of the anode electrode AE. The opening of the bank 130 can define an emission region of the subpixel SP. In this case, a region within the subpixel SP where the bank 130 is formed can be considered to correspond to a non-emission region.

The light emitting layer EL can be formed on the anode electrode AE. The light emitting layer EL can include, for example, an emission material that emits light of color of the corresponding subpixel SP or emits white light, such as an organic emission material. Here, the light emitting layer EL can be formed in a tandem structure, but not limited thereto.

The cathode electrode CE can be formed on the light emitting layer EL. The cathode electrode CE can be formed, for example, in a continuous form over the entire display region AA, corresponding to all subpixels SP.

In a case where the light emitting display device 10 is a bottom emission type display device, the cathode electrode CE can include, for example, a reflective layer formed of a highly reflective metal, such as Ag. In a case where the light emitting display device 10 is a top emission type display device, the cathode electrode CE can include, for example, a transparent conductive layer formed of a transparent conductive material, such as ITO or IZO.

As described above, each subpixel SP can include the light emitting diode OD formed in the emission region, including the anode electrode AE, the light emitting layer EL, and the cathode electrode CE.

In the subpixel SP configured as described above, the gate electrode Gd of the driving transistor Td (or an electrode pattern including the gate electrode Gd) can be formed to be positioned as far away from the data line DL as possible, as previously mentioned.

In this regard, referring to FIGS. 3 and 4, the gate electrode Gd of the driving transistor Td can be formed substantially parallel to the column direction which is the extension direction of the data line DL. In other words, the gate electrode Gd of the driving transistor Td can be arranged in a vertical type.

In addition, between the gate electrode Gd of the driving transistor Td and the data line DL, an electrode constituting the driving transistor Td, for example, the source electrode Sd or the storage capacitor Cst can be arranged. In other words, between the data line DL connected to the subpixel SP and the gate electrode Gd of the driving transistor Td in the subpixel SP, the source electrode Sd or the storage capacitor Cst, which is a circuit element within the subpixel SP, can be interposed.

As such, in this embodiment, the gate electrode Gd of the driving transistor Td can be arranged in a vertical type substantially parallel to the data line DL, and the source electrode Sd of the driving transistor Td or the storage capacitor Cst can be formed in a region between the gate electrode Gd of the driving transistor Td and the data line DL.

Accordingly, a separation distance (or separation space) between the gate electrode Gd of the driving transistor Td and the data line DL within the subpixel SP can be sufficiently secured.

As such, the separation distance between the gate electrode Gd of the driving transistor Td and the data line DL can be increased, thereby reducing or preventing parasitic capacitance between them.

Therefore, the distortion of the gate voltage of the driving transistor Td due to the data signal of the data line DL can be reduced or prevented, thereby reducing or preventing a vertical crosstalk caused by the parasitic capacitance.

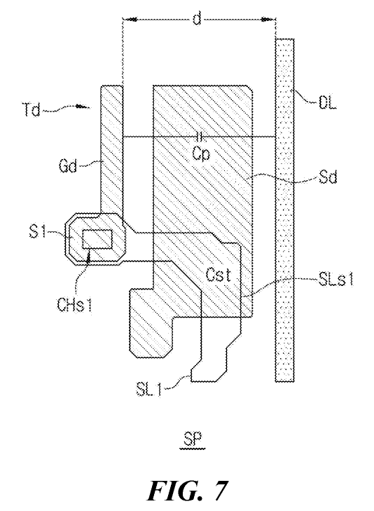

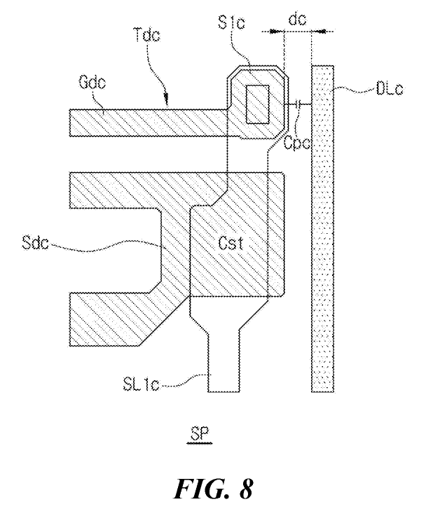

The improvement of the vertical crosstalk phenomenon of this embodiment can be described together with a comparative example. FIG. 7 is a plan view schematically illustrating an arrangement structure of a gate electrode of a driving transistor and a data line in a subpixel of a light emitting display device according to an embodiment of the present disclosure. FIG. 8 is a plan view schematically illustrating an arrangement structure of a gate electrode of a driving transistor and a data line in a subpixel of a light emitting display device according to a comparative example.

For convenience of explanation, FIGS. 7 and 8 are simplified focusing on a gate electrode of a driving transistor and a data line in a subpixel SP, and most other components in the subpixel SP are omitted.

Referring to FIG. 7, as previously mentioned, in the light emitting display device of this embodiment, the gate electrode Gd of the driving transistor Td can be arranged in a vertical type substantially parallel to the data line DL, and further, the source electrode Sd of the driving transistor Td or the storage capacitor Cst can be formed in the region between the gate electrode Gd of the driving transistor Td and the data line DL.

Accordingly, in this embodiment, a separation distance d between the gate electrode Gd of the driving transistor Td and the data line DL in the subpixel SP can be sufficiently secured, so that the parasitic capacitance Cp between the gate electrode Gd of the driving transistor Td and the data line DL can be reduced to a very small level or prevented.

However, referring to FIG. 8, in a light emitting display device of the comparative example, a gate electrode Gdc of a driving transistor Tdc extends in a horizontal direction that crosses the data line DLc and is arranged in a horizontal type close to the data line DLc, and no circuit element is substantially formed in a region between the gate electrode Gdc of the driving transistor Tdc and the data line DLc. Meanwhile, in FIG. 8, “Sdc” represents a source electrode of the driving transistor Tdc of the comparative example, “S1c” represents a source electrode of a first transistor of the comparative example, and “SL1c” represents a semiconductor layer of the first transistor of the comparative example.

Accordingly, in the comparative example, since a separation distance dc between the gate electrode Gdc of the driving transistor Tdc and the data line DLc in the subpixel SP becomes very small, a parasitic capacitance Cpc between the gate electrode Gdc of the driving transistor Tdc and the data line DLc becomes much larger than the parasitic capacitance Cp of this embodiment.

As such, according to this embodiment, the separation distance d between the gate electrode Gd of the driving transistor Td and the data line DL can be increased to a significant degree, thereby reducing or preventing the occurrence of the parasitic capacitance Cp between the gate electrode Gd of the driving transistor Td and the data line DL.

As described above, according to the embodiment of the present disclosure, the gate electrode of the driving transistor of the subpixel can be vertically arranged substantially parallel to the corresponding data line, and the circuit element such as the source electrode of the driving transistor and/or the storage capacitor can be formed in the region between the gate electrode of the driving transistor and the data line.

Accordingly, the separation distance between the gate electrode of the driving transistor and the data line in the subpixel can be sufficiently increased.

As such, the separation distance between the gate electrode of the driving transistor and the data line can be increased, thereby reducing or preventing the occurrence of parasitic capacitance between them.

Therefore, since the distortion of the gate voltage of the driving transistor caused by the data signal of the data line can be reduced or prevented, the vertical crosstalk phenomenon caused by the parasitic capacitance can be reduced or prevented, thereby improving image quality.

It will be apparent to those skilled in the art that various modifications and variation can be made in the present disclosure without departing from the spirit or scope of the disclosure. Thus, it is intended that the present disclosure cover the modifications and variations of this disclosure provided they come within the scope of the appended claims and their equivalents.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display device, comprising:
a substrate;
a data line disposed on the substrate, connected to a subpixel, and extending along a column direction on a side of the subpixel; and
a driving transistor and a light emitting diode in the subpixel, the light emitting diode being connected to a source electrode of the driving transistor, the driving transistor including a semiconductor layer,
wherein a gate electrode of the driving transistor extends along the column direction, and
wherein the source electrode of the driving transistor is disposed between the gate electrode of the driving transistor and the data line.

2. The light emitting display device of claim 1, further comprising a storage capacitor disposed in the subpixel, connected between the gate electrode and the source electrode of the driving transistor, and disposed between the gate electrode of the driving transistor and the data line.

3. The light emitting display device of claim 2, further comprising a first transistor disposed in the subpixel, and connected between the data line and the gate electrode of the driving transistor,
wherein a source region of a semiconductor layer of the first transistor connected to the gate electrode of the driving transistor forms a first capacitor electrode of the storage capacitor.

4. The light emitting display device of claim 3, further comprising a capacitor electrode pattern disposed below the semiconductor layer of the first transistor, and connected to the source electrode of the driving transistor,
wherein the source electrode of the driving transistor and the capacitor electrode pattern form a second capacitor electrode of the storage capacitor.

5. The light emitting display device of claim 4, wherein the source region of the semiconductor layer of the first transistor overlaps the source electrode of the driving transistor on the source region, and overlaps the capacitor electrode pattern.

6. The light emitting display device of claim 3, wherein a source electrode of the first transistor is formed integrally with the gate electrode of the driving transistor, and contacts the source region of the semiconductor layer of the first transistor.

7. The light emitting display device of claim 3, wherein a first insulating layer is located on a first metal layer in which the data line is formed,
wherein the semiconductor layer of the driving transistor and the semiconductor layer of the first transistor are located on the first insulating layer,
wherein a second insulating layer is located on each of the semiconductor layers of the driving transistor and the first transistor,
wherein a second metal layer in which the gate electrode, the source electrode, and a drain electrode of the driving transistor and a gate electrode, a source electrode, and a drain electrode of the first transistor are formed is located on the second insulating layer, and
wherein a third insulating layer is located on the second metal layer.

8. The light emitting display device of claim 7, wherein an anode electrode of the light emitting diode is located on the third insulating layer,
wherein a light emitting layer of the light emitting diode is located on the anode electrode, and
wherein a cathode electrode of the light emitting diode is located on the light emitting layer.

9. The light emitting display device of claim 3, further comprising a second transistor disposed in the subpixel, and connected between a reference line and the source electrode of the driving transistor.

10. The light emitting display device of claim 9, wherein a source electrode of the second transistor is formed integrally with the source electrode of the driving transistor.

11. The light emitting display device of claim 4, wherein the source region of the semiconductor layer of the first transistor is formed to extend across the capacitor electrode pattern and/or the source electrode of the driving transistor.

12. The light emitting display device of claim 11 , wherein the source region of the semiconductor layer of the first transistor is configured such that one end portion of the source region contacting a source electrode of the first transistor is located further away from the data line than the other end portion of the source region contacting a channel region of the semiconductor layer of the first transistor.

13. The light emitting display device of claim 7, further comprising a capacitor electrode pattern disposed in the first metal layer, the capacitor electrode pattern constituting one electrode of the storage capacitor.

14. A light emitting display device, comprising:
a substrate on which subpixels are arranged;
a data line disposed on the substrate, connected to each subpixel, and extending along a side of each subpixel; and
a driving transistor and a light emitting diode in each subpixel, the light emitting diode being connected to the driving transistor,
wherein a gate electrode of the driving transistor extends along an extension direction of the data line, and
wherein a circuit element included in the subpixel is disposed between the gate electrode of the driving transistor and the data line.

15. The light emitting display device of claim 14, wherein the circuit element included in the subpixel includes a source electrode of the driving transistor, a storage capacitor, or both.

16. The light emitting display device of claim 15, wherein the storage capacitor is connected between the gate electrode and the source electrode of the driving transistor.

17. The light emitting display device of claim 14, further comprising a first transistor disposed in the subpixel, and connected between the data line and the gate electrode of the driving transistor.

18. The light emitting display device of claim 17, wherein a source electrode of the first transistor is formed integrally with the gate electrode of the driving transistor, and contacts a source region of a semiconductor layer of the first transistor.

19. The light emitting display device of claim 17, further comprising a capacitor electrode pattern disposed below a semiconductor layer of the first transistor, and connected to a source electrode of the driving transistor.

20. The light emitting display device of claim 19, wherein a source region of the semiconductor layer of the first transistor is formed to extend across the capacitor electrode pattern and/or the source electrode of the driving transistor.
